(19) United States
(12) Patent Application Publication
(10) Pub. No.: US 2018/0175317 A1
(43) Pub. Date: Jun. 21, 2018

(54) LIGHT EMITTING ELEMENT

(71) Applicant: Industrial Technology Research Institute, Hsinchu (TW)

(72) Inventors: Jung-Yu Li, Hsinchu (TW); Yi-Ping Lin, Hsinchu (TW); Guan-Yu Chen, Hsinchu (TW); Jin-Han Wu, Hsinchu (TW); Shih-Pu Chen, Hsinchu (TW)

(21) Appl. No.: 15/474,150

(22) Filed: Mar. 30, 2017

(30) Foreign Application Priority Data
Dec. 15, 2016 (TW) 105141591

(51) Int. Cl. H01L 51/50; H01L 51/52

(52) U.S. Cl. CPC H01L 51/5036; H01L 51/5092; H01L 51/5206; H01L 51/5072; H01L 51/5221; H01L 51/5056

(57) ABSTRACT

A light emitting element is disclosed. The light emitting element includes a substrate, a metal layer and a metal electrode stacked on the substrate, and an organic material layer formed between the metal layer and the metal electrode. The metal layer includes a metal film and a plurality of metal particles having a size ranging from 5 nm to 25 nm and spaced apart from the metal electrode at a distance ranging between 75 nm and 130 nm. The organic material layer can generate light having chromaticity within a first range. When a voltage is applied across the metal layer and the metal electrode, a plasmon coupling occurs between the metal layer and the metal electrode, such that the chromaticity of the light generated by the organic material layer can be shifted from the first range to a second range.

### CROSS-REFERENCE TO RELATED APPLICATION

The present disclosure is based on, and claims priority from Taiwan Application Number 105141591, filed on Dec. 15, 2016, the disclosure of which is hereby incorporated by reference herein in its entirety.

### BACKGROUND

### 1. Technical Field

The present disclosure relates to light emitting elements, and, more particularly, to an organic light emitting element.

### 2. Description of Related Art

In general, light emitting diodes (LEDs) make use of semiconducting materials, which are turned into p-type and n-type materials through a process such as doping, and the p-type and n-type materials are then joined together to form a pn junction. Electrons and holes can be injected from the n-type and p-type materials, respectively, and when the electrons and the holes meet and combine with each other, energy will be released in the form of photons.

Organic light emitting diodes (OLEDs) use organic materials. The light emitting process of an organic light emitting diode is briefly described as follows: a forward bias is applied, so that the electrons and the holes overcome the interface energy barrier to be injected from the cathode and the anode, respectively, and they move towards each other under the influence of the electric field to form excitons in a light emitting layer. When the electrons and the holes combine in the light emitting layer, excitons disappear and emit light energy.

In recent years, the luminous efficiencies and the service lives of OLED red, green or blue light emitting materials have improved significantly, especially for the green light emitting materials. Although the luminous efficiency of the blue light emitting materials has increased over the years, but their service life is still not long enough.

Therefore, how to overcome the aforementioned problems, such as developing high efficiency OLED components without the need to use blue fluorescent/phosphorescent guest luminescent materials, remains a key issue in the market.

### SUMMARY

In an embodiment, the present disclosure provides a light emitting element, which may include: a metal layer having a non-planar surface, wherein the metal layer comprises a metal film and a plurality of metal particles of a size ranging between 5 nm and 25 nm; a metal electrode disposed above the metal layer and spaced apart from the metal layer at a distance ranging between 75 nm and 130 nm; an organic material layer formed between the metal layer and the metal electrode and configured for generating light having chromaticity within a first range, wherein a plasmon coupling occurs between the metal layer and the metal electrode, such that the chromaticity of the light generated by the organic material layer is shifted from the first range to a second range or a third range.

In another embodiment, the present disclosure provides a light emitting element, which may include: a metal layer having a non-planar surface, wherein the metal layer comprises a metal film and a plurality of metal particles; a metal electrode disposed above the metal layer, and spaced from the metal layer at a distance ranging between 120 nm and 350 nm that is one or ten times of a size of the metal particles; and an organic material layer formed between the metal layer and the metal electrode and configured for generating light having chromaticity within a first range, wherein a plasmon coupling occurs between the metal layer and the metal electrode, such that the chromaticity of the light generated by the organic material layer encompasses the first range, a second range and a third range.

### BRIEF DESCRIPTION OF THE DRAWINGS

The present disclosure can be more fully understood by reading the following detailed description of the embodiments, with reference made to the accompanying drawings, wherein:

FIGS. 1A and 1B are schematic diagrams depicting different aspects of an embodiment of a light emitting element in accordance with the disclosure;

FIGS. 2A and 2B are CIE chromaticity diagrams depicting shifting of chromaticity of lights from a light emitting element without metal particles and the light emitting element in accordance with the disclosure, respectively;

FIG. 2C is a graph depicting light extraction efficiencies of the light emitting element with metal particles and the light emitting element in accordance with the disclosure;

FIGS. 3A and 3B are schematic diagrams depicting structures of different aspects of an alternative embodiment of the light emitting element in accordance with the disclosure;

FIGS. 4A and 4B are schematic diagrams depicting structures of different aspects of an alternative embodiment of the light emitting element in accordance with the disclosure;

FIGS. 5A and 5B are schematic diagrams depicting structures of different aspects of an alternative embodiment of the light emitting element in accordance with the disclosure;

FIGS. 6A and 6B are schematic diagrams depicting structures of different aspects of an alternative embodiment of the light emitting element in accordance with the disclosure;

FIGS. 7A and 7B are schematic diagrams depicting structures of different aspects of an alternative embodiment of the light emitting element in accordance with the disclosure; and

FIG. 8 is a graph depicting lights of various bands of the light emitting element in accordance of the disclosure.

### DETAILED DESCRIPTION

The disclosure is described by the following specific embodiments. Those with ordinary skills in the arts can readily understand other advantages and functions of the disclosure after reading the disclosure of this specification. It should be noted that the structures, ratios, sizes shown in the drawings appended to this specification are to be construed in conjunction with the disclosure of this specification in order to facilitate understanding of those skilled in the art. They are not meant, in any ways, to limit the implementations of the disclosure. Any modifications to the structures, changes to the ratios and adjustments to the sizes without affecting the effects and objectives achieved by the disclosure should fall within the scope of the technical contents disclosed in the disclosure.

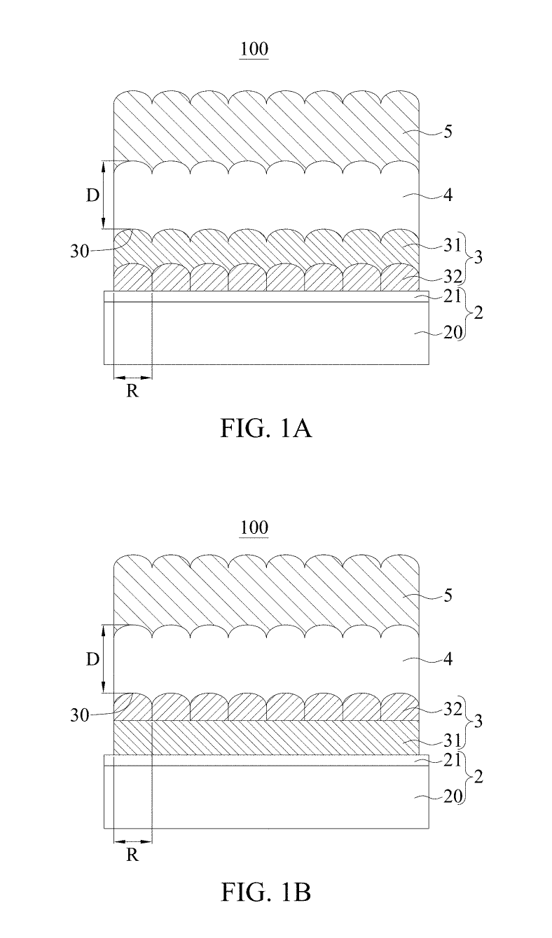

Referring to FIGS. 1A and 1B, a light emitting element 100 in accordance with the disclosure includes a metal layer 3, an organic material layer 4 and a metal electrode 5 stacked on a substrate 2 sequentially.

The substrate 2 can be transparent or semi-transparent, and can be, for example, made of glass, plastic, semiconductor such as silicon or silicide, or the like. The substrate 2 includes a body 20, and may or may not include a conductive layer 21, for example, can be made of conductive metal oxide, such as indium tin oxide (ITO) or indium zinc oxide (IZO). The substrate 2 including the conductive layer 21 can be used as an anode.

The metal layer 3 is formed on the substrate 2, includes a non-planar surface 30, and may include a metal film 31 and a plurality of metal particles 32. The metal particles 32 may or may not be in contact with the substrate 2, that is, the metal particles 32 can be disposed between the metal film 31 and the substrate 2, as shown in FIG. 1A, or between the metal film 31 and the organic material layer 4, as shown in FIG. 1B. The metal film 31 and the plurality of metal particles 32 can be made of the same or different materials, which may be metals or metal alloys, such as Ag, Al, Al/LiF, Ag/Al/Ag, Ag/Ge/Ag, or metal oxides, such as BCP/V₂O₅, MoO₃, ZnS/Ag/ZnO/Ag, ZnPc/C₆₀. The thickness of the metal layer 3 may range from 5 nm to 25 nm. The size R of the metal particles 32 may range from 5 nm to 25 nm.

The organic material layer 4 is formed between the metal layer 3 and the metal electrode 5, and can be made of a fluorescent or phosphorescent material, for example, a green phosphorescent 24 FTIr(acac) material. The organic material layer 4 may further include a hole injection layer (HIL), a hole transport layer (HTL), a emitting layer (EL), an electron transport layer (ETL) and an electron injection layer (EIL). Alternatively, the organic material layer 4 does not include the emitting layer, but a hole transport material and an electron transport material instead. The hole transport material and the electron transport material are in contact and interact with each other to generate exciplex for emitting light. The thickness of the organic material layer 4, i.e., the distance between the metal layer 3 and the metal electrode 5, ranges from 75 nm to 130 nm.

The metal electrode 5 is disposed above the organic material layer 4, so that the organic material layer 4 is sandwiched between the metal electrode 5 and the metal layer 3, forming a Metal-Dielectric-Metal (MDM) structure. The metal electrode 5 may be made of a metal or a metal alloy, such as Ag, Al, Al/LiF, Ag/Al/Ag, Ag/Ge/Ag, or a metal oxide, such as BCP/V₂O₅, MoO₃, ZnS/Ag/ZnO/Ag, ZnPc/C₆₀. The metal electrode 5 is typically used as a cathode.

When a voltage is applied across the substrate 2 (or the metal layer 3) and the metal electrode 5, the organic material layer 4 generates light having chromaticity within a first range. The distance D between the metal layer 3 and the metal electrode 5 ranges from 75 nm to 130 nm. Such a distance allows plasmon coupling to take place between the metal layer 3 and the metal electrode 5, which results in the chromaticity of the light generated by the organic material layer 4 being shifted on the chromaticity diagram. For example, when the distance D between the metal layer 3 and the metal electrode 5 is a first distance, the chromaticity of the light on the chromaticity diagram is shifted from the original first range to a second range; and when the distance D between the metal layer 3 and the metal electrode 5 is a second distance, the chromaticity of the light on the chromaticity diagram is shifted from the original first range to a third range.

The chromaticity diagram herein refers to an International Commission on Illumination (CIE) coordinate diagram. For example, when the distance D is between 75 nm to 130 nm, the first range can be a green range CIE (0-0.4, 0.5-0.7); the second range can be a blue range CIE (0.05-0.25, 0.03-0.5); and the third range can be a red range CIE (0.25-0.7, 0.25-0.45).

In an embodiment, the size R of the metal particles 32 ranges from 5 nm to 25 nm, which allows the surfaces of the metal film 31, the organic material layer 4 and the metal electrode 5 to have curves and bumps (non-planar surfaces) according to the size of the metal particles 32. The metal particles 32 with a specific size range not only allows the chromaticity of the light generated by the organic material layer 4 to shift further, but also allows light of the organic material layer 4 to be emitted out of the light emitting element 100.

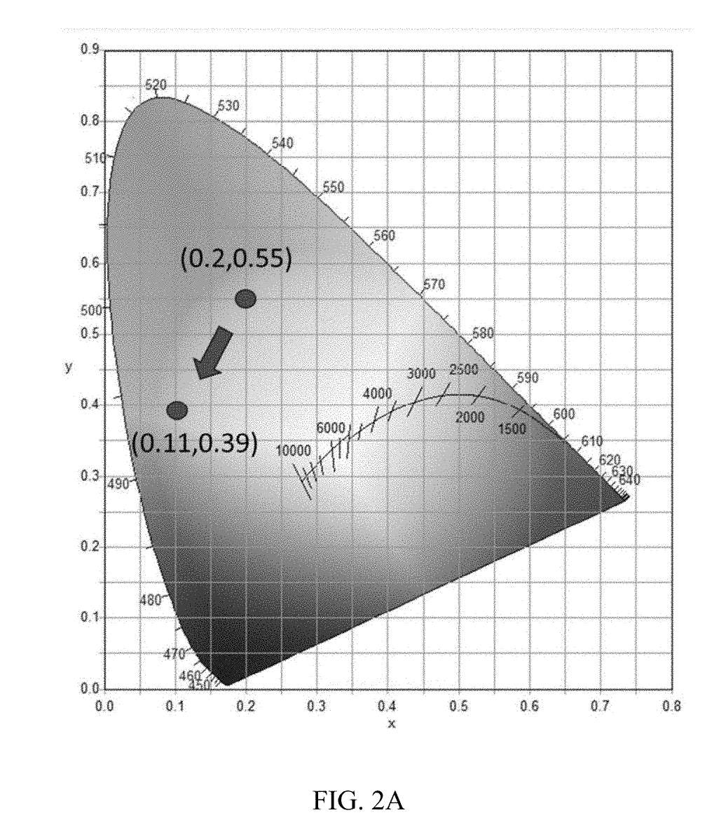

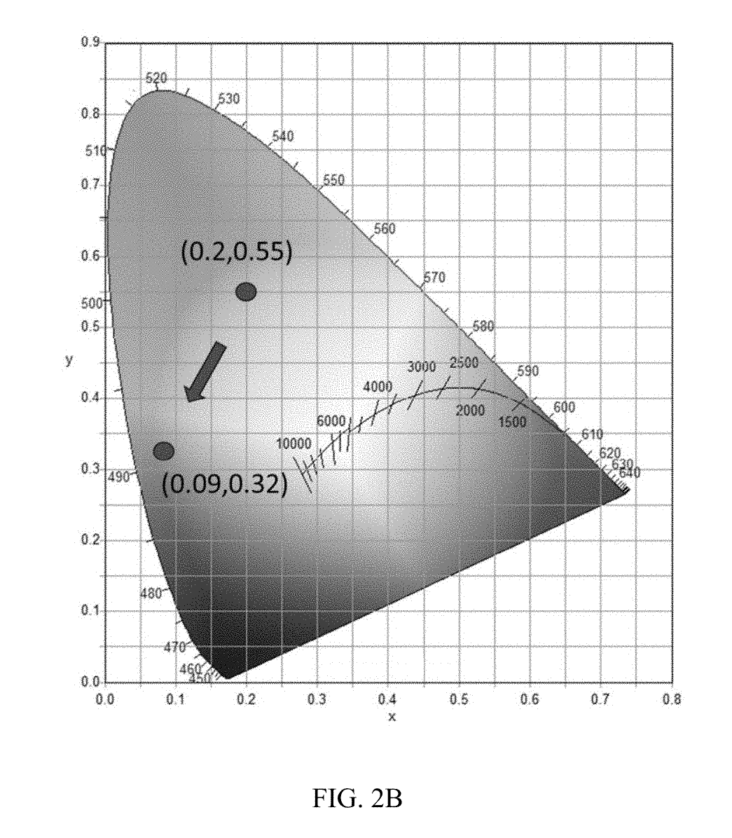

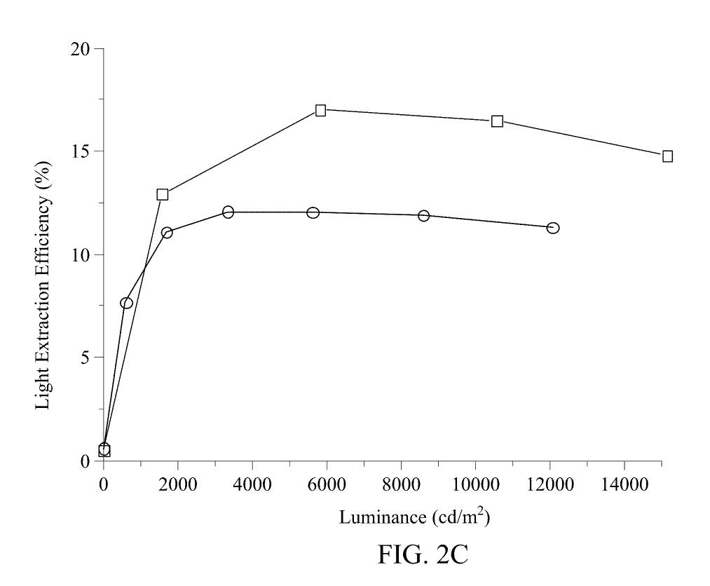

Referring to the chromaticity diagrams shown in FIGS. 2A and 2B, the chromaticity of the light is shifted further in the case of a light emitting element including the metal particles (FIG. 2B) (e.g., from (0.2, 0.55) to (0.09, 0.32) on the chromaticity diagram) compared to that in the case of a light emitting element without the metal particles in FIG. 2A (e.g., from (0.2, 0.55) to (0.11, 0.39) on the chromaticity diagram). In terms of external quantum efficiency (EQE) that indicates the light extraction efficiency of the light emitting element, as shown in FIG. 2C, compared to the case where there is no metal nano particles (indicated by circles), the light emitting element with metal nano particles (indicated by squares) have a higher light extraction efficiency, meaning that gain occurs in the light in the second range. It can be appreciated from the above that, in the disclosure, a metal layer consisting of metal particles and a metal film is used as one of the metal layers in the MDM structure, a metal electrode is used as the other metal layer in the MDM structure, and by selecting a distance between the metal layer and the metal electrode and the size of the metal particles, a light emitting element emitting a light in desired CIE coordinates can be obtained. For example, a light emitting element employing an organic material layer with CIE coordinates in the green light range (CIE (0-0.4, 0.5-0.7)) can emit a blue light (CIE (0.05-0.25, 0.03-0.5)) or a red light (CIE (0.25-0.7, 0.25-0.45)). Furthermore, as the distance between the metal layer 3 and the metal electrode 5 becomes smaller or the thickness of the metal layer 3 becomes larger, the CIE coordinates will shift further towards to the blue light range. On the other hand, as the distance between the metal layer 3 and the metal electrode 5 becomes larger or the thickness of the metal layer 3 becomes smaller, the CIE coordinates will shift further towards to the red light range.

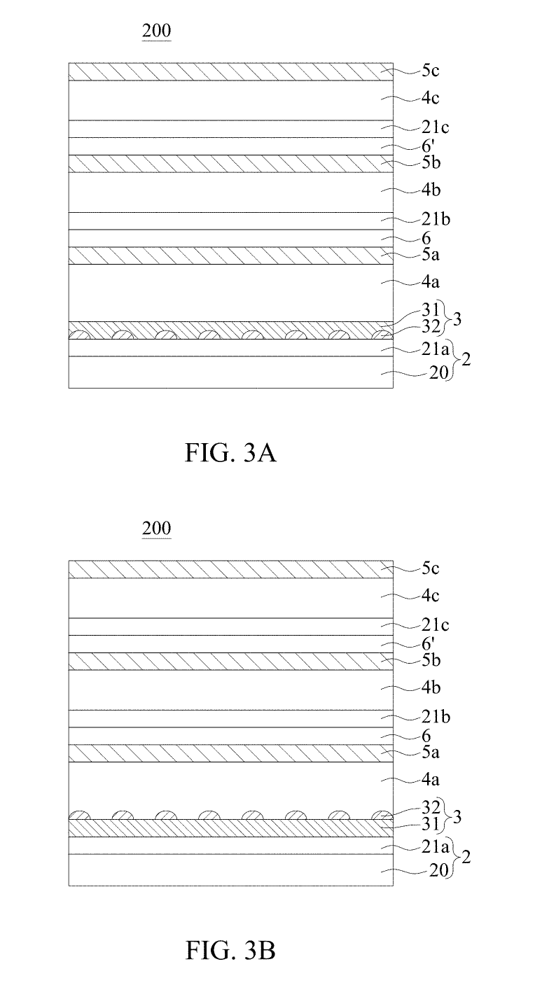

Referring to FIGS. 3 to 6, alternative implementations of the light emitting element 100 with respect to FIG. 1A or 1B are shown.

Referring to FIGS. 3A and 3B, a light emitting element 200 includes a substrate 2 (which may include a conductive layer 21a), a metal layer 3 including a metal film 31 and metal particles 32 (the metal layer 3 can be used as a first electrode), a first organic material layer 4a, a first metal electrode 5a, a second electrode 21b, a second organic material layer 4b, a second metal electrode 5b, a third electrode 21c, a third organic material layer 4c and a third metal electrode 5c sequentially stacked, and a first transparent insulating layer 6 formed between the first metal electrode 5a and the second electrode 21b, and a second transparent insulating layer 6′ formed between the second metal electrode 5b and the third electrode 21c. The metal particles 32 may be in contact with the substrate 2, that is, the metal particles 32 are between the metal film 31 and the substrate 2, as shown in FIG. 3A; or they may not be in contact with the substrate 2, that is, the metal particles 32 are between the first organic material layer 4a and the metal film 31, as shown in FIG. 3B. It should be noted that the upper surfaces of the metal film 31, the first organic material layer 4a, the first metal electrode 5a, and various other layers formed above the metal particles 32 will have non-planar curves and bumps (not shown) according to the shape of the metal particles 32.

In the embodiments shown in FIGS. 3A and 3B, when a first voltage is applied across the substrate 2 (or the metal layer 3) and the first metal electrode 5a, the chromaticity of a first light generated by the first organic material layer 4a will be shifted from an original first range to a second range on the CIE coordinate system; when a second voltage is applied across the second electrode 21b and the second metal electrode 5b, the second organic material layer 4b generates a second light with a chromaticity in the first range on the CIE coordinate system; and when a third voltage is applied across the third electrode 21c and the third metal electrode 5c, the third organic material layer 4c generates a third light with a chromaticity in the third range on the CIE coordinate system. Moreover, three separate driving circuits can be connected between the first metal electrode 5a and the substrate 2 (or the metal layer 3), between the second metal electrode 5b and the second electrode 21b, and between the third metal electrode 5c and the third electrode 21c, respectively, for controlling the application of the first voltage, the second voltage and the third voltage so as to obtain a light emitting element 200 with an adjustable light.

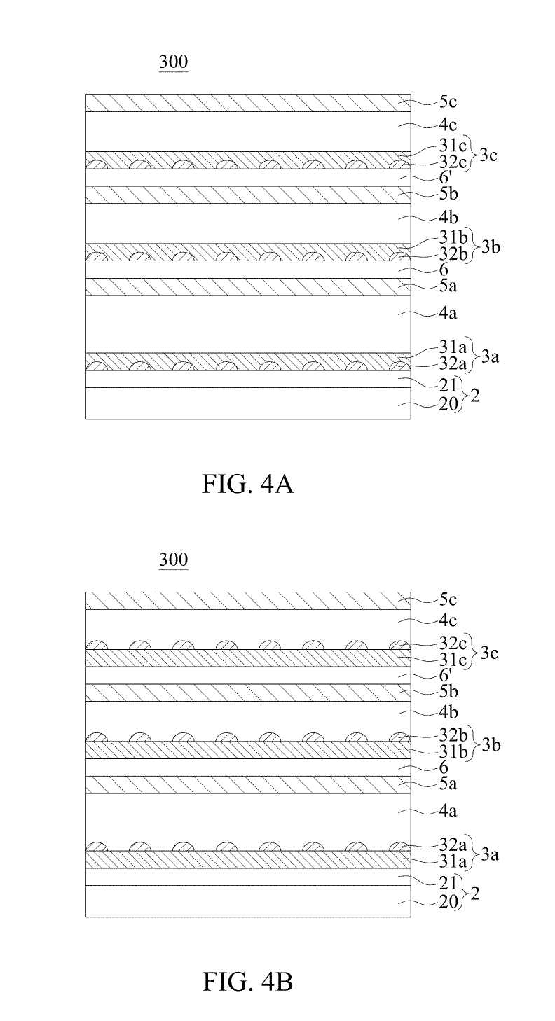

Referring to FIGS. 4A and 4B, a light emitting element 300 includes a substrate 2 (which may include a conductive layer 21), a first metal layer 3a including a first metal film 31a and first metal particles 32a, a first organic material layer 4a, a first metal electrode 5a, a second metal layer 3b including a second metal film 31b and second metal particles 32b, a second organic material layer 4b, a second metal electrode 5b, a third metal layer 3c including a third metal film 31c and third metal particles 32c, a third organic material layer 4c and a third metal electrode 5c sequentially stacked, and a first transparent insulating layer 6 formed between the first metal electrode 5a and the second metal layer 3b, and a second transparent insulating layer 6′ formed between the second metal electrode 5b and the third metal layer 3c. The first metal particles 32a may be between the first metal film 31a and the substrate 2 (i.e., in contact with the substrate 2); the second metal particles 32b may be between the second metal film 31b and the first transparent insulating layer 6 (i.e., in contact with the transparent insulating layer 6); and the third metal particles 32c may be between the third metal film 31c and the second transparent insulating layer 6′ (i.e., in contact with the second transparent insulating layer 6′), such as those shown in FIG. 4A. Alternatively, the first metal particles 32a may be between the first organic material layer 4a and the first metal film 31a (i.e., not in contact with the substrate 2); the second metal particles 32b may be between the second organic material layer 4b and the second metal film 31b (i.e., not in contact with the first transparent insulating layer 6); and the third metal particles 32c may be between the third organic material layer 4c and the third metal film 31c (i.e., not in contact with the second transparent insulating layer 6′), such as those shown in FIG. 4B. It should be noted that the upper surfaces of the first metal film 31a, the first organic material layer 4a and the first metal electrode 5a will have non-planar curves and bumps (not shown) according to the shape of the first metal particles 32a; the upper surfaces of the second metal film 31b, the second organic material layer 4b and the second metal electrode 5b will have non-planar curves and bumps (not shown) according to the shape of the second metal particles 32b; and the upper surfaces of the third metal film 31c, the third organic material layer 4c and the third metal electrode 5c will have non-planar curves and bumps (not shown) according to the shape of the third metal particles 32c.

In the embodiments shown in FIGS. 4A and 4B, when a first voltage is applied across the substrate 2 (or the first metal layer 3a) and the first metal electrode 5a, the chromaticity of a first light generated by the first organic material layer 4a will be shifted from an original first range to a second range on the CIE coordinate system; when a second voltage is applied across the second metal layer 3b and the second metal electrode 5b, the second organic material layer 4b generates a second light in the first range with a gain; and when a third voltage is applied across the third metal layer 3c and the third metal electrode 5c, the chromaticity of a third light generated by the first organic material layer 4a will be shifted from the original first range to a third range on the CIE coordinate system. However, the stacked structure is not limited as such. Moreover, three separate driving circuits can be connected between the first metal electrode 5a and the substrate 2 (or the first metal layer 3a), between the second metal electrode 5b and the second metal layer 3b, and between the third metal electrode 5c and the third metal layer 3c, respectively, for controlling the application of the first voltage, the second voltage and the third voltage, thereby obtaining a light emitting element 300 with an adjustable light.

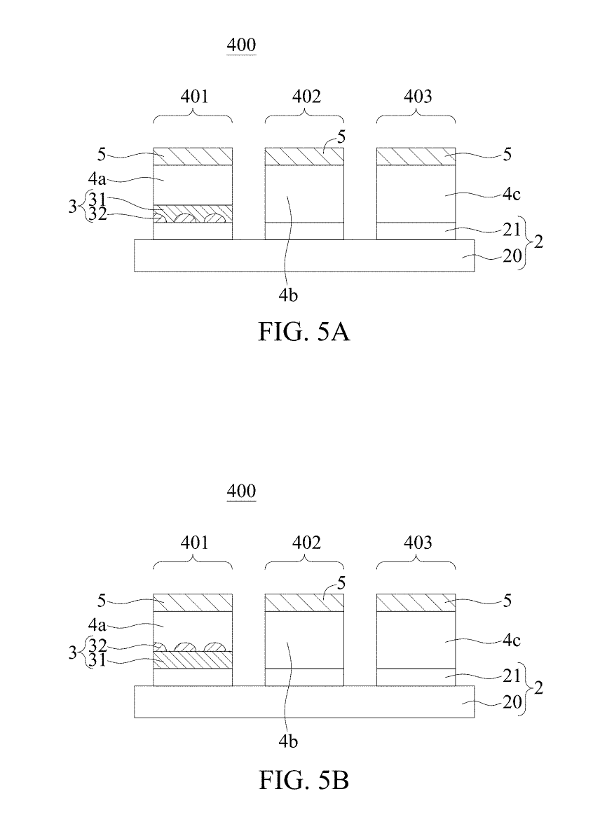

Referring to FIGS. 5A and 5B, a light emitting element 400 includes sub-elements 401, 402 and 403 arranged side by side and spaced apart from one another at an interval on the substrate 2. Each sub-element includes a conductive layer 21 of the substrate 2 and a metal electrode 5 stacked on the substrate 2. In an embodiment, the sub-element 401 further includes a metal layer 3 including a metal film 31 and a plurality of metal particles 32 disposed between the substrate 2 and a first organic material layer 4a. The sub-element 402 further includes a second organic material layer 4b formed between the substrate 2 and the metal electrode 5. The sub-element 403 further includes a third organic material layer 4c formed between the substrate 2 and the metal electrode 5. The metal particles 32 may be disposed between the metal film 31 and the substrate 2 (i.e., in contact with the substrate 2), such as that shown in FIG. 5A; or the metal particles 32 may be disposed between the first organic material layer 4a and the metal film 31 (i.e., not in contact with the substrate 2), such as that shown in FIG. 5B. In an embodiment, the upper surfaces of the metal film 31, the first organic material layer 4a and the metal electrode 5 will have non-planar curves and bumps (not shown) according to the shape of the metal particles 32.

In the embodiments shown in FIGS. 5A and 5B, when voltages are applied across the conductive layer 21 of the substrate 2 (or the metal layers 3) and the metal electrodes 5, the chromaticity of a first light generated by the first organic material layer 4a will be shifted from an original first range to a second range on the CIE coordinate system, the second organic material layer 4b generates a second light with a chromaticity in the first range on the CIE coordinate system, and the third organic material layer 4c generates a third light with a chromaticity in the third range on the CIE coordinate system. The metal electrodes 5 of the sub-elements 401, 402 and 403 can be connected to respective driving circuits. In other words, three separate driving circuits can be provided between the metal electrode 5 and the metal layer 3 (or the conductive layer 21) of the sub-element 401, between the metal electrode 5 and the conductive layer 21 of the sub-element 402, and between the metal electrode 5 and the conductive layer 21 of the sub-element 403, respectively, for controlling the voltages applied to the sub-elements 401, 402 and 403, thereby obtaining a light emitting element 400 with an adjustable light.

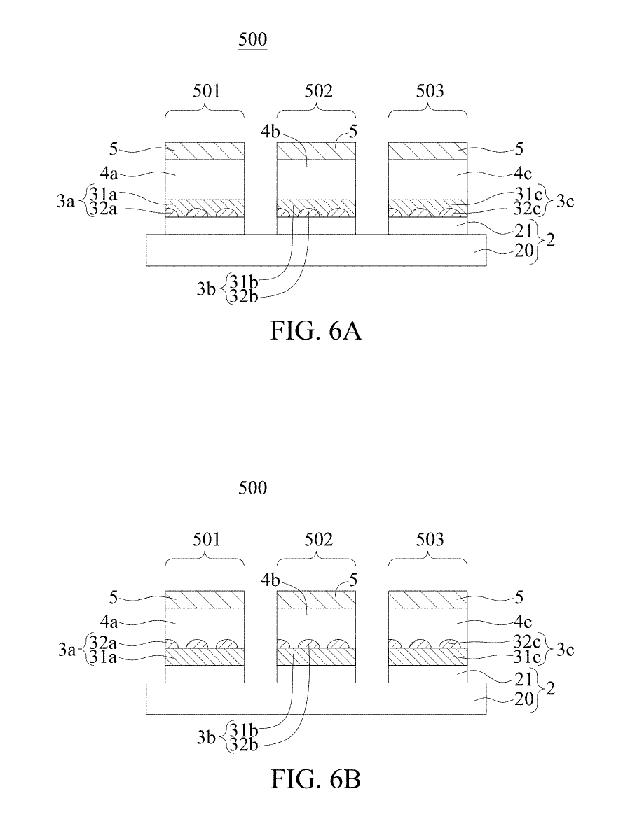

Referring to FIGS. 6A and 6B, a light emitting element 500 includes sub-elements 501, 502 and 503 arranged side by side and spaced apart from one another at an interval on the substrate 2. Each sub-element includes a conductive layer 21 of the substrate 2 and a metal electrode 5 stacked on the substrate 2. In an embodiment, the sub-element 501 further includes a first organic material layer 4a and a first metal layer 3a including a first metal film 31a and a plurality of first metal particles 32a formed between the substrate 2 and the metal electrode 5. The sub-element 502 further includes a second organic material layer 4b and a second metal layer 3b including a second metal film 31b and a plurality of second metal particles 32b formed between the substrate 2 and the metal electrode 5. The sub-element 503 further includes a third organic material layer 4c and a third metal layer 3c including a third metal film 31c and a plurality of third metal particles 32c disposed between the substrate 2 and the metal electrode 5. The first metal particles 32a, the second metal particles 32b and the third metal particles 32c may be respectively disposed between the first metal film 31a and the substrate 2 (i.e., in contact with the substrate 2), the second metal film 31b and the substrate 2 (i.e., in contact with the substrate 2), and the third metal film 31c and the substrate 2 (i.e., in contact with the substrate 2), such as those shown in FIG. 6A. Alternatively, the first metal particles 32a, the second metal particles 32b and the third metal particles 32c may be respectively disposed between the first organic material layer 4a and the first metal film 31a, the second organic material layer 4b and the second metal film 31b, the third organic material layer 4c and the third metal film 31c (i.e., not in contact with the substrate 2), such as those shown in FIG. 6B. In an embodiment, the upper surfaces of the first metal film 31a, the second metal film 31b, the third metal film 31c, the first organic material layer 4a, the second organic material layer 4b, the third organic material layer 4c and the metal electrode 5 will have non-planar curves and bumps (not shown) according to the shapes of first metal particles 32a, the second metal particles 32b and the third metal particles 32c, respectively.

In the embodiments shown in FIGS. 6A and 6B, when voltages are applied across the conductive layer 21 of the substrate 2 (or the first metal layers 3a) and the metal electrode 5, the second metal layer 3b and the metal electrode 5, and the third metal layer 3c and the metal electrode 5, the chromaticity of a first light generated by the first organic material layer 4a will be shifted from an original first range to a second range on the CIE coordinate system; the second organic material layer 4b generates a second light in the first range with a gain; and the chromaticity of a third light generated by the third organic material layer 4c will be shifted from an original first range to a third range on the CIE coordinate system. The metal electrodes 5 or the first metal layer 3a, the second metal layer 3b, the third metal layer 3c of the sub-elements 501, 502 and 503 can be connected to respective driving circuits. In other words, three separate driving circuits can be provided between the metal electrode 5 and the conductive layer 21 (or the first metal layer 3a) of the sub-element 501, between the metal electrode 5 and the second metal layer 3b or the conductive layer 21 of the sub-element 502, and between the metal electrode 5 and the third metal layer 3c or the conductive layer 21 of the sub-element 503, respectively, for controlling the voltages applied to the sub-elements 501, 502 and 503, thereby obtaining a light emitting element 500 with an adjustable light.

For example, the first range can be a green light range CIE (0-0.4, 0.5-0.7), the second range can be a blue light range CIE (0.04-0.25, 0.03-0.5), the third range can be a red light range CIE (0.25-0.7, 0.25-0.45), and the light emitting elements 200, 300, 400 and 500 may emit white light. Moreover, with circuit design and fabrication, current can be fed into various sub-elements, while controlling the light intensity of each sub-element, thereby generating a light source with an adjustable color.

Therefore, the light emitting elements in accordance with the disclosure provide metal layer(s), organic material layer(s) and metal electrode(s) stacked vertically or horizontally, and the metal layers in accordance with the disclosure include metal films and a plurality of metal particles in specific size ranges, thereby obtaining light emitting elements that emit white light.

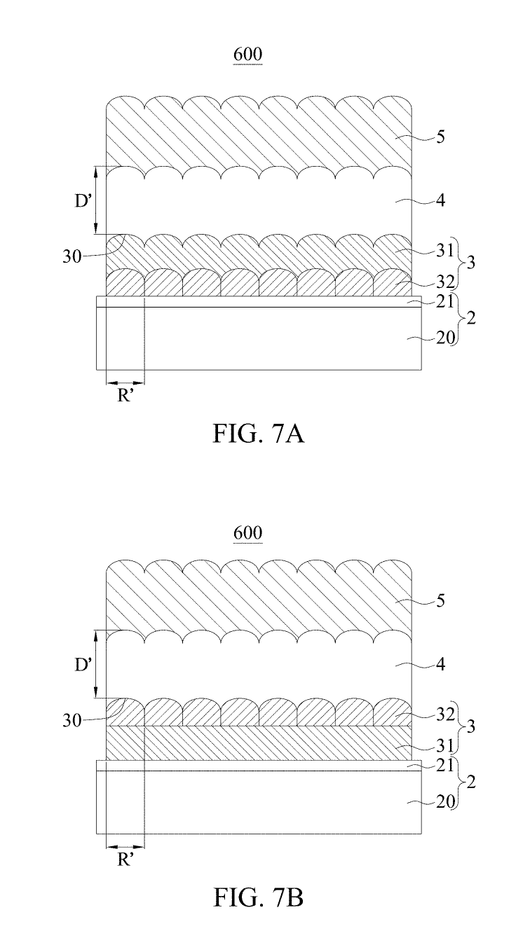

Referring to FIGS. 7A and 7B, the structure and materials of various layers in a light emitting element 600 are similar to those of the light emitting element 100 described with respect to FIGS. 1A and 1B. Their difference is that the distance D′ between the metal layer 3 and the metal electrode 5 ranges from 120 nm and 350 nm, and the size R′ of the metal particles 32 is 0.1 to 1 time of the distance D′, that is, the distance D′ is 1 or 10 times of a size of the size R′ of the metal particles 32.

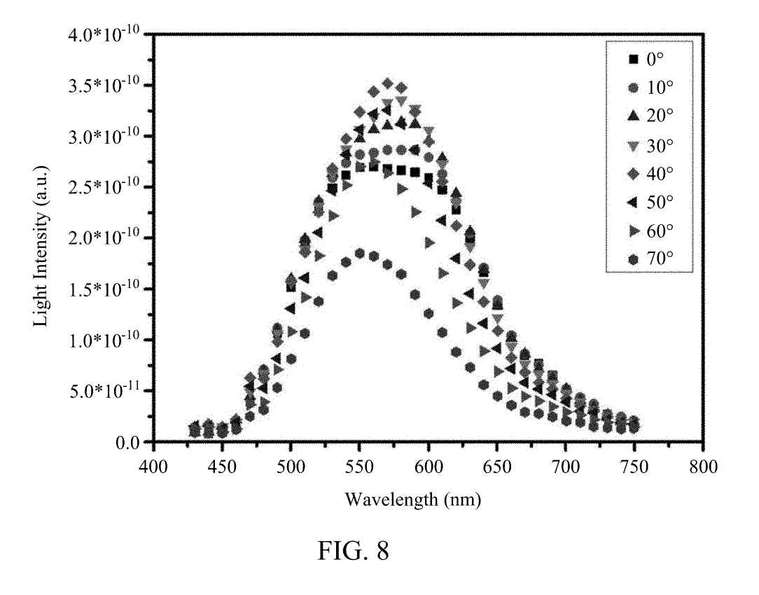

When a voltage is applied across the substrate 2 or the metal layer 3 and the metal electrode 5, the organic material layer 4 generates light having chromaticity shifted to various bands on the CIE coordinate system. The metal particles 32 further allow the light generated by the organic material layer 4 with the shifted chromaticity on the CIE coordinates to be emitted outwardly from the light emitting element 600. As a result, the light emitting element 600 is capable of emitting white light. For example, the organic material layer can be made of a green fluorescent material Alq3, as shown in FIG. 8, which shows white lights mixed by lights of various bands. Viewing angles with respect to the light emitting element 600 are indicated in the legend provided on the right side of the graph. For example, 0° represented by a square means that a viewer is right at the front of the light emitting element 600.

Therefore, in the disclosure, the metal layer consisting of the metal particles and the metal film is used as one of the metal layers in the MDM structure, the metal electrode is used as the other metal layer in the MDM structure, and by configuring the distance between the metal layer and the metal electrode and the size of the metal particles, the organic material layer can generate a light in the desired CIE coordinates, thus allowing the light emitting element to emit white light. Therefore, it can also be applied to light-emitting elements of active matrix organic light-emitting diodes or passive matrix organic light-emitting diodes.

The above embodiments are only used to illustrate the principles of the disclosure, and should not be construed as to limit the disclosure in any way. The above embodiments can be modified by those with ordinary skill in the art without departing from the scope of the disclosure as defined in the following appended claims.

What is claimed is:

1. A light emitting element, comprising:
a metal layer having a non-planar surface, and comprising a metal film and a plurality of metal particles of a size ranging between 5 nm and 25 nm;
a metal electrode disposed above the metal layer and spaced apart from the metal layer at a distance ranging between 75 nm and 130 nm; and
an organic material layer formed between the metal layer and the metal electrode and configured for generating light having chromaticity within a first range,
wherein a plasmon coupling occurs between the metal layer and the metal electrode, such that the chromaticity of the light generated by the organic material layer is shifted from the first range to a second range or a third range.

2. The light emitting element of claim 1, wherein the first range is (0-0.4, 0.5-0.7) on a chromaticity diagram, the second range is (0.05-0.25, 0.03-0.5) on the chromaticity diagram, and the third range is (0.25-0.7, 0.25-0.45) on the chromaticity diagram.

3. The light emitting element of claim 2, wherein as the distance between the metal layer and the metal electrode gets smaller or a thickness of the metal layer gets larger, the chromaticity of the light on the chromaticity diagram is shifted from the first range to the second range, and as the distance between the metal layer and the metal electrode gets larger or the thickness of the metal layer gets smaller, the chromaticity of the light on the chromaticity diagram is shifted from the first range to the third range.

4. The light emitting element of claim 1, further comprising a substrate carrying the metal layer, the organic material layer and the metal electrode, wherein the plurality of metal particles are disposed between the metal film and the substrate or between the organic material layer and the metal film.

5. The light emitting element of claim 4, wherein the substrate or the metal layer is used as one of an anode and a cathode, the metal electrode is used as another one of the anode and the cathode, and the organic material layer includes a hole injection layer, a hole transport layer, a light emitting layer, an electron injection layer and an electron transport layer, or includes a hole transport material and an electron transport material.

6. The light emitting element of claim 1, wherein the light has a gain in the second range.

7. The light emitting element of claim 1, wherein the metal layer is used as a first electrode, the organic material layer is a first organic material layer, the light generated by the first organic material layer is first light, the metal electrode is a first metal electrode, and the light emitting element further includes:
a second electrode disposed above the first metal electrode;
a second metal electrode disposed above the second electrode;
a second organic material layer formed between the second electrode and the second metal electrode and configured for generating second light having chromaticity within the first range;
a third electrode disposed above the second metal electrode;
a third metal electrode disposed above the third electrode;
a third organic material layer formed between the third electrode and the third metal electrode and configured for generating third light having chromaticity within the third range;
a first transparent insulating layer formed between the first metal electrode and the second electrode; and
a second transparent insulating layer formed between the second metal electrode and the third electrode.

8. The light emitting element of claim 7, wherein the first range is (0-0.4, 0.5-0.7) on a chromaticity diagram, the second range is (0.05-0.25, 0.03-0.5) on the chromaticity diagram, and the third range is (0.25-0.7, 0.25-0.45) on the chromaticity diagram.

9. The light emitting element of claim 7, further comprising a substrate carrying the first electrode, the first organic material layer, the first metal electrode, the first transparent insulating layer, the second electrode, the second organic material layer, the second metal electrode, the second transparent insulating layer, the third electrode, the third organic material layer and the third metal electrode, wherein the plurality of metal particles are disposed between the metal film and the substrate or between the first organic material layer and the metal film.

10. The light emitting element of claim 9, wherein the substrate or the first electrode and the second electrode and the third electrode each is used as one of an anode and a cathode, the first metal electrode, the second metal electrode and the third metal electrode each is used as another one of the anode and the cathode, and the first organic material layer, the second organic material layer and the third organic material layer each includes a hole injection layer, a hole transport layer, a light emitting layer, an electron injection layer and an electron transport layer, or includes a hole transport material and an electron transport material.

11. The light emitting element of claim 7, further comprising three driving circuits connected between the first electrode and the first metal electrode, the second electrode and the second metal electrode, and the third electrode and the third metal electrode, respectively, such that light of the light emitting element is adjustable.

12. The light emitting element of claim 1, wherein the metal layer is a first metal layer, the metal film is a first metal film, the metal particles are first metal particles, the organic material layer is a first organic material layer, the light generated by the first organic material layer is first light, the metal electrode is a first metal electrode, and the light emitting element further includes:
a second metal layer disposed above the first metal electrode, and including a second metal film and a plurality of second metal particles of a size ranging between 5 nm and 25 nm;
a second metal electrode disposed above the second metal layer and spaced apart from the second metal layer at a distance ranging between 75 nm and 130 nm;
a second organic material layer formed between the second metal layer and the second metal electrode and configured for generating second light having a gain and chromaticity within the first range;
a third metal layer disposed above the second metal electrode, and including a third metal film and a plurality of third metal particles of a size ranging between 5 nm and 25 nm;
a third metal electrode disposed above the third metal layer and spaced apart from the third metal layer at a distance ranging between 75 nm and 130 nm;
a third organic material layer formed between the third metal layer and the third metal electrode and configured for generating third light having chromaticity that is shifted from the first range to the third range;
a first transparent insulating layer formed between the first metal electrode and the second metal layer; and
a second transparent insulating layer formed between the second metal electrode and the third metal layer.

13. The light emitting element of claim 12, wherein the first range is (0-0.4, 0.5-0.7) on a chromaticity diagram, the second range is (0.05-0.25, 0.03-0.5) on the chromaticity diagram, and the third range is (0.25-0.7, 0.25-0.45) on the chromaticity diagram.

14. The light emitting element of claim 12, further comprising a substrate carrying the first metal layer, the first organic material layer, the first metal electrode, the first transparent insulating layer, the second metal layer, the second organic material layer, the second metal electrode, the second transparent insulating layer, the third metal layer, the third organic material layer and the third metal electrode, wherein the plurality of first metal particles are disposed between the first metal film and the substrate or between the first organic material layer and the first metal film, the plurality of second metal particles are disposed between the second metal film and the first transparent insulating layer or between the second organic material layer and the second metal film, and the plurality of third metal particles are disposed between the third metal film and the second transparent insulating layer or between the third organic material layer and the third metal film.

15. The light emitting element of claim 14, wherein the substrate or the first metal layer and the second metal layer and the third metal layer each is used as one of an anode and a cathode, the first metal electrode, the second metal electrode and the third metal electrode each is used as another one of the anode and the cathode, and the first organic material layer, the second organic material layer and the third organic material layer each includes a hole injection layer, a hole transport layer, a light emitting layer, an electron injection layer and an electron transport layer, or includes a hole transport material and an electron transport material.

16. The light emitting element of claim 12, further comprising three driving circuits connected between the first metal layer and the first metal electrode, the second metal layer and the second metal electrode, and the third metal layer and the third metal electrode, respectively, such that light of the light emitting element is adjustable.

17. The light emitting element of claim 1, wherein the organic material layer is a first organic material layer, the light generated by the organic material layer is a first light, and the light emitting element further includes:
a second organic material layer arranged side by side with the first organic material layer and configured for generating second light having chromaticity within the first range; and
a third organic material layer arranged side by side with the first organic material layer and the second organic material layer and configured for generating third light having chromaticity within the third range.

18. The light emitting element of claim 17, wherein the first range is (0-0.4, 0.5-0.7) on a chromaticity diagram, the second range is (0.05-0.25, 0.03-0.5) on the chromaticity diagram, and the third range is (0.25-0.7, 0.25-0.45) on the chromaticity diagram.

19. The light emitting element of claim 17, further comprising a substrate carrying the first organic material layer, the second organic material layer and the third organic material layer side by side with one another, wherein the plurality of metal particles are disposed between the metal film and the substrate or between the first organic material layer and the metal film.

20. The light emitting element of claim 19, wherein the metal layer or the substrate is used as one of an anode and a cathode, the metal electrode is used as another one of the anode and the cathode, and the first organic material layer, the second organic material layer and the third organic material layer each includes a hole injection layer, a hole transport layer, a light emitting layer, an electron injection layer and an electron transport layer, or includes a hole transport material and an electron transport material.

21. The light emitting element of claim 17, further comprising three driving circuits, wherein portions of the metal electrode corresponding to the first organic material layer, the second organic material layer and the third organic material layer are spaced apart from one another and electrically connected to the three driving circuits, respectively, such that light of the light emitting element is adjustable.

22. The light emitting element of claim 1, wherein the metal layer is a first metal layer, the metal film is a first metal film, the metal particles are first metal particles, the organic material layer is a first organic material layer, the light generated by the first organic material layer is first light, and the light emitting element further includes:
a second metal layer arranged side by side with the first metal layer, and including a second metal film and a plurality of second metal particles of a size ranging between 5 nm and 25 nm and spaced apart from the metal electrode at a distance ranging between 75 nm and 130 nm;
a second organic material layer formed between the second metal layer and the metal electrode, arranged side by side with the first organic material layer, and configured for generating second light having a gain and chromaticity within the first range;
a third metal layer arranged side by side with the first metal layer and the second metal layer, and including a third metal film and a plurality of third metal particles of a size ranging between 5 nm and 25 nm and spaced apart from the metal electrode at a distance ranging 75 nm and 130 nm; and
a third organic material layer formed between the third metal layer and the metal electrode, arranged side by side with the first organic material layer and the second organic material layer, and configured for generating third light having chromaticity that is shifted from the first range to the third range.

23. The light emitting element of claim 22, wherein the first range is (0-0.4, 0.5-0.7) on a chromaticity diagram, the second range is (0.05-0.25, 0.03-0.5) on the chromaticity diagram, and the third range is (0.25-0.7, 0.25-0.45) on the chromaticity diagram.

24. The light emitting element of claim 22, further comprising a substrate carrying the first metal layer, the second metal layer and the third metal layer arranged side by side with one another, and the first organic material layer, the second organic material layer and the third organic material layer arranged side by side with one another, wherein the plurality of first metal particles are disposed between the first metal film and the substrate or between the first organic material layer and the first metal film, the plurality of second metal particles are disposed between the second metal film and the substrate or between the second organic material layer and the second metal film, and the plurality of third metal particles are disposed between the third metal film and the substrate or between the third organic material layer and the third metal film.

25. The light emitting element of claim 24, wherein the substrate or the first metal layer and the second metal layer and the third metal layer each is used as one of an anode and a cathode, the metal electrode is used as another one of the anode and the cathode, and the first organic material layer, the second organic material layer and the third organic material layer each includes a hole injection layer, a hole transport layer, a light emitting layer, an electron injection layer and an electron transport layer, or includes a hole transport material and an electron transport material.

26. The light emitting element of claim 22, further comprising three driving circuits, wherein portions of the metal electrode corresponding to the first organic material layer, the second organic material layer and the third organic material layer are spaced apart from one another, the first metal layer and its corresponding metal electrode, the second metal layer and its corresponding metal electrode, and the third metal layer and its corresponding metal electrode are electrically connected to the three driving circuits, respectively, such that light of the light emitting element is adjustable.

27. A light emitting element, comprising:
a metal layer having a non-planar surface, and comprising a metal film and a plurality of metal particles;
a metal electrode disposed above the metal layer, and spaced from the metal layer at a distance ranging between 120 nm and 350 nm that is one or ten times of a size of the metal particles; and
an organic material layer formed between the metal layer and the metal electrode and configured for generating light having chromaticity within a first range,
wherein a plasmon coupling occurs between the metal layer and the metal electrode, such that the chromaticity of the light generated by the organic material layer encompasses the first range, a second range and a third range.

28. The light emitting element of claim 27, wherein the first range is (0-0.4, 0.5-0.7) on a chromaticity diagram, the second range is (0.05-0.25, 0.03-0.5) on the chromaticity diagram, and the third range is (0.25-0.7, 0.25-0.45) on the chromaticity diagram.

29. The light emitting element of claim 27, further comprising a substrate carrying the metal layer, the organic material layer and the metal electrode, wherein the plurality of metal particles are disposed between the metal film and the substrate or between the organic material layer and the metal film.

30. The light emitting element of claim 29, wherein the substrate or the metal layer is used as one of an anode and a cathode, the metal electrode is used as another one of the anode and cathode, and the organic material layer includes a hole injection layer, a hole transport layer, a light emitting layer, an electron injection layer and an electron transport layer, or includes a hole transport material and an electron transport material.
